(19) United States
(12) Patent Application Publication
(10) Pub. No.: US 2025/0364032 A1
(43) Pub. Date: Nov. 27, 2025

(54) MEMORY DEVICES WITH DATA SECURITY CIRCUITRY, AND ASSOCIATED SYSTEMS, DEVICES, AND METHODS

(71) Applicant: Micron Technology, Inc., Boise, ID (US)

(72) Inventors: Chen-Whai Sheng, Taichung (TW); Debra M. Bell, Boise, ID (US); Bo Sheng Zheng, Taichung (TW); Jing Wen, Taichung (TW); Masayoshi Yamazaki, Tokyo (JP)

(21) Appl. No.: 19/211,251

(22) Filed: May 18, 2025

Related U.S. Application Data
(60) Provisional application No. 63/650,215, filed on May 21, 2024.

(51) Int. Cl. G11C 11/4078; G11C 11/4072; G11C 11/4076

(52) U.S. Cl. CPC G11C 11/4078; G11C 11/4072; G11C 11/4076

(57) ABSTRACT

Memory devices with data security circuitry (and associated systems, devices, and methods) are disclosed herein. In one embodiment, an apparatus includes a memory array having a plurality of memory cells, a plurality of DQ terminals, and circuitry configured to, upon each initialization of the apparatus, (i) set a data transfer pattern for the apparatus to a random one of a plurality of data transfer patterns for the apparatus, and/or (ii) set a burst swap order for the apparatus to a random one of a plurality of burst swap orders for the apparatus. Each data transfer pattern can define a different allocation of memory cells of the memory array to DQ terminals of the plurality of DQ terminals. Additionally, or alternatively, each burst swap order can define a different order in which the apparatus is configured to parallelize or serialize data received or output, respectively, via the plurality of DQ terminals.

### CROSS-REFERENCE TO RELATED APPLICATION(S)

The present application claims priority to U.S. Provisional Patent Application No. 63/650,215, filed May 21, 2024, the disclosure of which is incorporated herein by reference in its entirety.

### TECHNICAL FIELD

The present disclosure relates generally to semiconductor devices. For example, several embodiments of the present disclosure are directed to memory devices with data security circuitry that, upon each initialization of the memory devices, randomize pairings between data (DQ) terminals and memory cells of the memory devices (e.g., to hinder access of data across different power cycles).

### BACKGROUND

Memory devices are widely used to store information related to various electronic devices such as computers, wireless communication devices, cameras, digital displays, and the like. Memory devices are frequently provided as internal, semiconductor, integrated circuits, and/or external removable devices in computers or other electronic devices. There are many different types of memory, including volatile and non-volatile memory. Volatile memory, including static random- access memory (SRAM), dynamic random-access memory (DRAM), and synchronous dynamic random-access memory (SDRAM), among others, lose stored data after power supplied to the volatile memory is interrupted. In some cases, however, the data loss is not immediate. Thus, data remaining on the volatile memory after a power down or power loss event may still be retrievable from the volatile memory.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1A is a partially schematic block diagram of a memory system configured in accordance with various embodiments of the present technology.

FIG. 1B is a partially schematic block diagram of a memory device configured in accordance with various embodiments of the present technology.

FIG. 2 is a partially schematic diagram of a memory system configured in accordance with various embodiments of the present technology.

FIGS. 2A-2C are partially schematic diagrams of alternative examples of data terminal patterns configured in accordance with various embodiments of the present technology.

FIG. 3A is a flowchart illustrating a method for scrambling data in accordance with various embodiments of the present technology.

FIG. 3B is a flowchart illustrating another method for scrambling data in accordance with various embodiments of the present technology.

FIG. 4 is a schematic view showing a system comprising a semiconductor device assembly that can include memory devices configured in accordance with various embodiments of the present technology.

### DETAILED DESCRIPTION

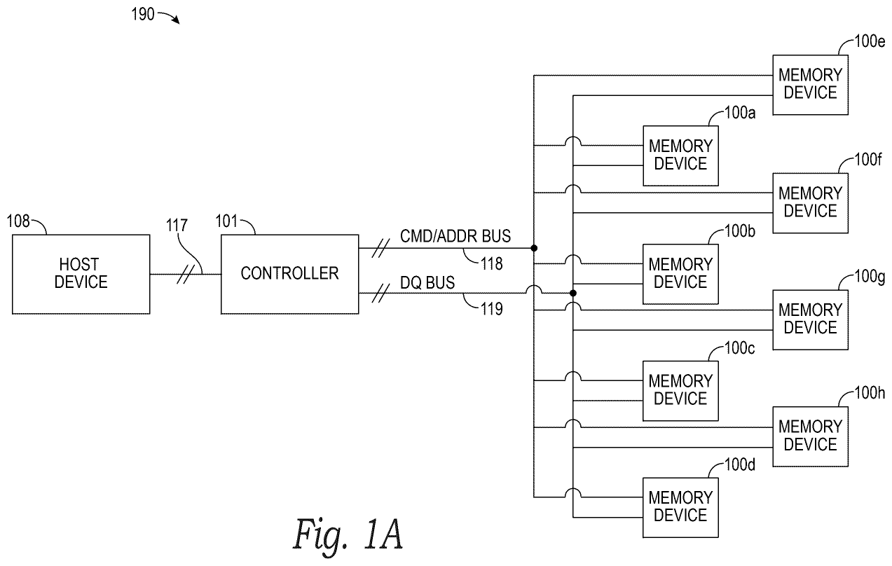

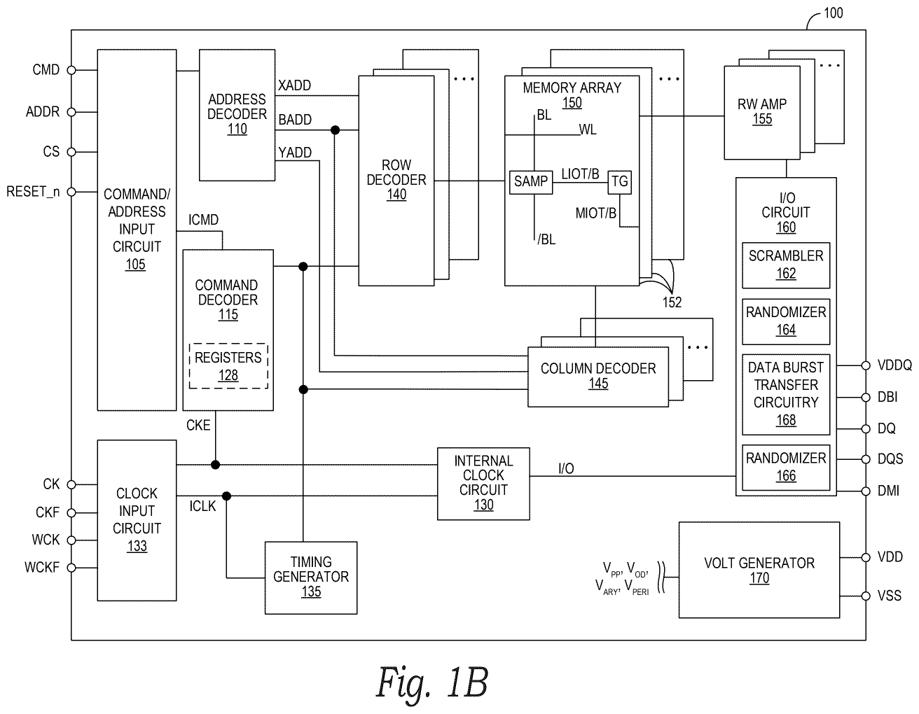

The present disclosure is generally directed to memory devices with data security circuitry, and associated systems, devices, and methods. For example, several embodiments described in detail below are directed to memory devices that randomize data (DQ) terminal assignments (and thereby randomize data storage to memory cells of the memory devices and/or data readout via DQ terminals of the memory devices) upon initialization of the memory devices. As another example, several embodiments described in detail below are directed to memory devices that randomize, upon initialization of the memory devices, an order in which data is serialized and/or parallelized when the memory devices operate in a burst mode. As still another example, several embodiments described in detail below are directed to memory devices that, upon initialization of the memory devices, randomize both (a) DQ terminal assignments and (b) the order in which data is serialized and/or parallelized when the memory devices operate in a burst mode. A person skilled in the art will understand that the technology may have additional embodiments and that the technology may be practiced without several of the details of the embodiments described below with reference to FIGS. 1A-4.

In the illustrated embodiments below, the memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

### A. Overview

Semiconductor memory devices may store information in an array of memory cells. The information may be stored as a binary code, and each memory cell may store a bit of information as cither a logical high (e.g., a “1”) or a logical low (e.g., a “0”). The memory cells may be organized at the intersection of word lines (rows) and bit lines (columns). The memory may further be organized into one or more memory banks, each of which may include a plurality of rows and columns. During operations, the memory device may (a) receive a command and an address which specifies one or more rows and one or more columns and (b) execute the command on the memory cells corresponding to the address.

Although volatile memory devices typically begin to lose their stored data when power is no longer supplied to the memory devices, the data loss is not immediate and can be prolonged by cooling memory devices to low temperatures. As such, there is a risk that data stored to the volatile memory devices can be accessed without authorization by cooling the memory devices to low temperatures, quickly swapping the memory devices from one memory system to another, and then attempting to access the data stored to the memory devices.

To address these concerns, the present technology is generally directed to memory devices that include data security circuitry that, upon each initialization of the memory devices, randomize data (DQ) terminal assignments and/or burst orders to hinder access of data across initialization and/or different power cycles of the memory devices. In accordance with one aspect of the present disclosure, a memory device (or other apparatus) can include a memory array with a plurality of memory cells, a plurality of DQ terminals operably coupled to the memory array, and data security circuitry. The data security circuitry can include a randomizer and a scrambler. In some embodiments, the randomizer of the data security circuitry can be configured to generate a random value upon each initialization of the memory device. In turn, the scrambler of the data security circuitry can newly set a data transfer pattern (e.g., DQ terminal assignments or pairings) based at least in part on each random value generated by the randomizer. Each data transfer pattern can define which set of memory cells in the memory array the memory device uses to store data received at a given one of the DQ terminals. Additionally, or alternatively, each data transfer pattern can define which one of the DQ terminals the memory device uses to read out data stored to a given set of memory cells in the memory array. For example, as data is received at the DQ terminals of a memory device, the scrambler can scramble the data and store the scrambled data to memory cells of the memory array in accordance with a first data transfer pattern that is set by the scrambler based on a first random value generated by the randomizer the last time the memory device was initialized. Thereafter, as long as the memory device utilizes the first data transfer pattern, the data can, in accordance with the first data transfer pattern, be read out of the memory array, unscrambled by the scrambler, and transferred to a connected host device in an unscrambled state via the DQ terminals of the memory device. In some embodiments, the memory device can utilize a same data transfer pattern until a next initialization of the memory device (e.g., following a power down event, a power loss event, receipt of a reset command, etc.).

Continuing with the above example, if (after storing data to the memory array using the first data transfer pattern) the memory device experiences a power down event, a power loss event, a reset command, or other event that causes initialization of the memory device, the randomizer of the data security circuitry can newly generate a second random value that the scrambler uses to newly set a second data transfer pattern for the memory device. Assuming that the second random value produced by the randomizer is different from the first random value produced by the randomizer described above, the second data transfer pattern set by the scrambler will differ from the first data transfer pattern described above. As a result, when the data that was stored to the memory array in accordance with the first data transfer pattern is read out from the memory array in accordance with the second data transfer pattern after the initialization of the memory device, the scrambler will further scramble (as opposed to unscramble) the data such that the data is output to a connected host device in a scrambled and/or uninterpretable state, thereby maintaining security of the data across the initialization of the memory device.

In some embodiments, the data security circuitry can additionally, or alternatively, include a second randomizer and/or data burst transfer circuitry. The second randomizer can be configured to generate a burst order random value upon each initialization of the memory device. In turn, the scrambler and/or the data burst transfer circuitry can newly set a burst swap pattern based at least in part on each burst order random value generated by the second randomizer. Each burst swap pattern can define an order in which, during a burst mode of the memory device, data is serialized and stored to the memory cells of the memory array and/or is parallelized and read out of the memory device (e.g., to a connected host device). For example, as data is received at the memory device, the scrambler and/or the data burst transfer circuitry can serialize and store the data in the memory array in accordance with a first burst swap pattern that is based on a first random value generated by the second randomizer. Thereafter, as long as the memory device utilizes the first burst swap pattern, the data can, in accordance with the first burst swap pattern, be read out of the memory array, parallelized by the scrambler and/or the data burst transfer circuitry, and transferred to a connected host device in an unscrambled state via the DQ terminals of the memory device. In some embodiments, the memory device can utilize a same burst swap pattern until a next initialization of the memory device (e.g., following a power down event, a power loss event, receipt of a reset command, etc.).

Similar to the data transfer pattern example described above, if (after storing data to the memory array using the first burst swap pattern) the memory device experiences a power down event, a power loss event, a reset command, or other event that causes initialization of the memory device, the second randomizer of the data security circuitry can newly generate a second random value that the scrambler and/or the data burst transfer circuitry uses to newly set a second burst swap pattern for the memory device. Assuming that the second random value produced by the second randomizer is different from the first random value discussed above, the second burst swap pattern set by the scrambler and/or the data burst transfer circuitry will differ from the first burst swap pattern discussed above. As a result, when data that was stored to the memory array in accordance with the first burst swap pattern is read out from the memory array in accordance with the second burst swap order after the initialization of the memory device, the scrambler and/or the data burst transfer circuitry will further scramble (as opposed to unscramble) the data as it parallelizes the data such that the data is output to a connected host device in a scrambled and/or uninterpretable state, thereby maintaining security of the data across the initialization of the memory device.

The present technology therefore is expected to offer several advantages. For example, a memory device configured in accordance with various embodiments of the present technology can internally manage (a) setting data transfer patterns and/or burst swap patterns and (b) scrambling/unscrambling data. Thus, a connected host device remains unaware of data transfer patterns and/or burst swap patterns implemented in the memory device, making it difficult for the connected host device to unscrambled data it receives from the memory device in a scrambled state. As another example, even though cooling a memory device configured in accordance with various embodiments of the present technology may decrease the rate of data loss following an interruption of power supplied to the memory device, the interruption of power (e.g., at any temperature) can cause the memory device to implement a different data transfer pattern and/or a different burst swap pattern after power is restored to the memory device and/or the memory device is initialized. As a result, the memory device can maintain security of data stored to the memory device across different power cycles of the memory device. Stated another way, while lowering the temperature of a memory device configured in accordance with various embodiments of the present technology may delay and/or prevent the memory device from irretrievably losing stored data while the memory device is swapped between systems, lowering the temperature does not enable correct descrambling of data stored to the memory device and therefore is expected to thwart such attempts at accessing the data without authorization. Moreover, the data security circuitry described herein is relatively minimal, easy to implement, and relatively low-cost. Additionally, or alternatively, use of the data security circuitry is expected to provide robust data security with little to no operational drawbacks such as timing latency, increased power consumption, and/or increased complexity of user interactions.

### B. Selected Embodiments of Memory Systems and Associated Devices and Methods

FIG. 1A is a block diagram schematically illustrating a memory system 190 (e.g., a dual in-line memory module (DIMM)) configured in accordance with various embodiments of the present technology. In the illustrated embodiment, the memory system 190 includes a module or rank of memory devices 100 (identified individually as memory devices 100a-100h in FIG. 1A), a controller 101, and a host device 108. In some embodiments, the memory devices 100 can be DRAM memory devices. Although illustrated with a single module/rank of eight memory devices 100 in FIG. 1A, the memory system 190 can include a greater or lesser number of memory devices 100 and/or memory modules/ranks in other embodiments of the present technology. Well-known components of the memory system 190 have been omitted from FIG. 1A and are not described in detail below so as to avoid unnecessarily obscuring aspects of the present technology.

The memory devices 100 can be connected to one or more electronic devices that are capable of utilizing memory for temporary or persistent storage of information, or a component thereof. For example, one or more of the memory devices 100 can be operably connected to one or more host devices. As a specific example, the memory devices 100 of the memory system 190 illustrated in FIG. 1A are connected to a host device 101 (also referred to herein as “memory controller 101” or “control circuit 101”) and to a host device 108 (also referred to herein as “CPU 108”).

The memory devices 100 of FIG. 1A are operably connected to the memory controller 101 via a command/address (CMD/ADDR) bus 118 and a data (DQ) bus 119. As described in greater detail below with respect to FIG. 1B, the CMD/ADDR bus 118 and the DQ bus 119 can be used by the memory controller 101 to communicate commands, memory addresses, and/or data to the memory devices 100. In response, the memory devices 100 can execute commands received from the memory controller 101. For example, in the event a write command is received from the memory controller 101 over the CMD/ADDR bus 118, the memory devices 100 can receive data from the memory controller 101 over the DQ bus 119 and can write the data to memory cells corresponding to memory addresses received from the memory controller 101 over the CMD/ADDR bus 118. As another example, in the event a read command is received from the memory controller 101 over the CMD/ADDR bus 118, the memory devices 100 can output data to the memory controller 101 over the DQ bus 119 from memory cells corresponding to memory addresses received from the memory controller 101 over the CMD/ADDR bus 118.

The host device 108 of FIG. 1A may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 108 may be a networking device (e.g., a switch, a router, etc.); a recorder of digital images, audio, and/or video; a vehicle; an appliance; a toy; or any one of a number of other products. In one embodiment, the host device 108 may be connected directly to one or more of the memory devices 100 (e.g., via a communications bus of signal traces (not shown)). Additionally, or alternatively, the host device 108 may be indirectly connected to one or more of the memory device 100 (e.g., over a networked connection or through intermediary devices, such as through the memory controller 101 and/or via a communications bus 117 of signal traces).

As discussed further herein, each of the memory devices 100 can include circuitry (also referred to herein as “data security circuitry,” “data security scramble circuitry,” “scramble circuitry,” “data security subsystems,” and the like) for protecting data stored to the memory devices 100 from unauthorized access (e.g., following a power down event, a power loss event, receipt of a reset command, or other event that causes the memory devices 100 to execute an initialization routine). For example, each of the memory devices 100 can include circuitry that can, upon each initialization of the respective memory device 100, randomize pairings (also referred to herein as “DQ terminal assignments”) between data (DQ) terminals and memory cells of that memory device 100. Thus, during a period of time between sequential (e.g., consecutive, subsequent, immediately subsequent, successive) initializations of a memory device 100, data received at one of the memory devices 100 can be scrambled at the time that the data is stored to the memory device 100, and can be unscrambled at the time that the data is read out from the memory device 100 because the DQ terminal assignments for that memory device 100 remain unchanged for that period of time. When, however, the memory device 100 next executes an initialization routine (e.g., after power supplied to the memory device 100 is interrupted, such as when the memory device 100 is restarted, when the memory device 100 is powered down, or when the memory device 100 experiences a power loss event; or after the memory device 100 is otherwise prompted to execute the initialization routine, such as after the memory device 100 is reset in response to a reset command), the data security circuitry of the memory device 100 can rerandomize the DQ terminal assignments. As a result, the DQ terminal assignments used to read and/or write data following execution of the initialization routine are unlikely to match the DQ terminal assignments used to read and/or write data prior to execution of the initialization routine. Therefore, any data that was scrambled and stored to the memory device 100 prior to the execution of the initialization routine is unlikely to be unscrambled as it is read out of the memory device 100 after the execution of the initialization routine. In other words, any data that was stored to the memory device 100 prior to a given execution of an initialization routine and read out after that given execution will likely be read out from the memory device 100 in a scrambled and/or uninterpretable state.

Thus, for example, when the memory device 100 is swapped from the memory system 190 to another system (not shown) in an attempt to gain unauthorized access to data stored to the memory device 100, the memory device 100 experiences a power loss event during the swapping procedure, and data security circuitry of the memory device 100 randomizes the DQ terminal assignments upon initialization of the memory device 100 after power is restored to the memory device 100 within the other system. As a result, there is a high probability (a) that the DQ terminal assignments following initialization of the memory device 100 in the other system do not match the DQ terminal assignments used by the memory device 100 in the memory system 190 prior to the swap, and (b) that any data stored to the memory device 100 prior to the initialization of the memory device 100 in the other system is read out from the memory device 100 following the initialization of the memory device 100 in the other system in a scrambled and uninterpretable state.

FIG. 1B is a block diagram schematically illustrating one of the memory devices 100 configured in accordance with various embodiments of the present technology. The memory device 100 may include an array of memory cells, such as memory array 150. The memory array 150 may include a plurality of banks 152 (e.g., banks 0-15 in the example of FIG. 1B), and each bank may include a plurality of word lines (WL), a plurality of bit lines (BL), and a plurality of memory cells (e.g., m×n memory cells) arranged at intersections of the word lines (e.g., m word lines, which may also be referred to as rows) and the bit lines (e.g., n bit lines, which may also be referred to as columns). Each word line of the plurality may be coupled with a corresponding word line (WL) driver configured to control a voltage of the word line during memory operations.

Memory cells can include any one of a number of different memory media types, including capacitive, phase change, magnetoresistive, ferroelectric, or the like. The selection of a word line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least one respective main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and address bus (e.g., the CMD/ADDR bus 118 of FIG. 1A) to receive command signals CMD and address signals ADDR, respectively. The memory device may further include a chip select terminal to receive a chip select signal CS; a reset terminal to receive a reset signal RESET_n that can be used to reset or otherwise initialize hardware of the memory device 100; clock terminals to receive clock signals CK and CKF; data clock terminals to receive data clock signals WCK and WCKF; data terminals to receive data signals DQ, DQS or RDQS, DBI (for data bus inversion function), and DMI (for data mask inversion function); and power supply terminals to receive power supply potentials VDD, VSS, and VDDQ.

The power supply potentials VDD and VSS can be supplied to an internal voltage generator circuit 170. The internal voltage generator circuit 170 can generate various internal potentials V_{PP}, V_{OD}, V_{ARY}, V_{PERI}, and the like based on the power supply potentials VDD and VSS. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply potential VDDQ can be provided to an input/output circuit 160 of the memory device 100, together with the power supply potential VSS. The power supply potential VDDQ can be the same potential as the power supply potential VDD in some embodiments of the present technology. The power supply potential VDDQ can be a different potential from the power supply potential VDD in other embodiments of the present technology. The dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 133. The CK and CKF signals can be complementary, and the WCK and WCKF signals can be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 133 can receive the external clock signals. For example, when enabled by a CKE signal from a command decoder 115 of the memory device 100, an input buffer can receive the CK and CKF signals and the WCK and WCKF signals. The clock input circuit 133 can receive the external clock signals to generate internal clock signals ICLK. The internal clock signals ICLK can be supplied to an internal clock circuit 130. The internal clock circuit 130 can provide various phase and frequency controlled internal clock signals based on the internal clock signals ICLK received from the clock input circuit 130 and the clock enable signal CKE received from the command decoder 115.

For example, the internal clock circuit 130 can include a clock path (not shown in FIG. 1B) that receives the internal clock signal ICLK and provides various clock signals to the command decoder 115. The internal clock circuit 130 can further provide input/output (I/O) clock signals. The I/O clock signals can be supplied to the input/output circuit 160 and can be used as a timing signal for determining an output timing of read data and an input timing of write data. The I/O clock signals can be provided at multiple clock frequencies so that data can be output from and input into the memory device 100 at different data rates. A higher clock frequency may be desirable when high memory speed is desired. A lower clock frequency may be desirable when lower power consumption is desired. The internal clock signals ICLK can also be supplied to a timing generator 135 that can generate various internal clock signals.

The command terminals and address terminals may be supplied with an address signal and a bank address signal from outside the memory device 100. The address signal and the bank address signal supplied to the address terminals can be transferred, via a command/address input circuit 105, to an address decoder 110. The address decoder 110 can receive the address signals and supply a decoded row address signal (XADD) to the row decoder 140 (which may be referred to as a row driver), and a decoded column address signal (YADD) to the column decoder 145 (which may be referred to as a column driver). The address decoder 110 can also receive the bank address portion of the ADDR input and supply the decoded bank address signal (BADD) to both the row decoder 140 and the column decoder 145.

The command and address terminals may be supplied with command signals CMD, address signals ADDR, chip select signals CS, and reset signals RESET_n from a memory controller. The command signals CMD may represent various memory commands received from the memory controller (e.g., refresh commands, activate commands, precharge commands, access commands, which can include read commands and write commands). The chip select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to the command decoder 115 via the command/address input circuit 105. The reset signals RESET_n may be used to initialize (e.g., reset) hardware of the memory device 100, such as the command/address input circuit 105, status registers, state machines and the like, such as during power up of the memory device 100. As described in greater detail below, the reset signals RESET_n can prompt the memory device 100 to rerandomize DQ terminal assignments and/or burst swap orders.

The command decoder 115 may include circuits to decode the internal command signals ICMD to generate various internal signals and commands for performing memory operations (e.g., a row command signal to select a word line and a column command signal to select a bit line). Other examples of memory operations that the memory device 100 may perform based on decoding the internal command signals ICMD includes a refresh command (e.g., re-establishing full charges stored in individual memory cells of the memory array 150), an activate command (e.g., activating a row in a particular bank, in some cases for subsequent access operations), or a precharge command (e.g., deactivating the activated row in the particular bank). The internal command signals can also include output and input activation commands, such as clocked command CMDCK (not shown in FIG. 1B).

The command decoder 115, in some embodiments, may further include one or more registers 128 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 128 (or a subset of the registers 128) may be referred to as mode registers. Additionally, or alternatively, the memory device 100 may include registers 128 as a separate component outside of the command decoder 115. In some embodiments, the registers 128 may include multi-purpose registers (MPRs) configured to write and/or read specialized data to and/or from the memory device 100.

When a read command is issued to a bank with an open row and a column address is timely supplied as part of the read command, read data can be read from memory cells in the memory array 150 designated by the row address (which may have been provided as part of the activate command identifying the open row) and column address. The read command may be received by the command decoder 115, which can provide internal commands to an input/output circuit 160 so that read data can be output from the data terminals DQ, DQS or RDQS, DBI, and DMI via read/write amplifiers 155 and the input/output circuit 160 according to DQS or RDQS clock signals. The read data may be provided at a time defined by read latency information that can be programmed in the memory device 100, for example, in a mode register (e.g., one or more of the registers 128). The read latency information can be defined in terms of clock cycles of the clock signal CK. For example, the read latency information can be a number of clock cycles of the clock signal CK after the read command is received by the memory device 100 when the associated read data is provided.

When a write command is issued to a bank with an open row and a column address is timely supplied as part of the write command, write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency information. The write latency information can be programmed in the memory device 100, for example, in a mode register (e.g., one or more of the registers 128). The write latency information can be defined in terms of clock cycles of the clock signal CK. For example, the write latency information can be a number of clock cycles of the clock signal CK after the write command is received by the memory device 100 when the associated write data is received.

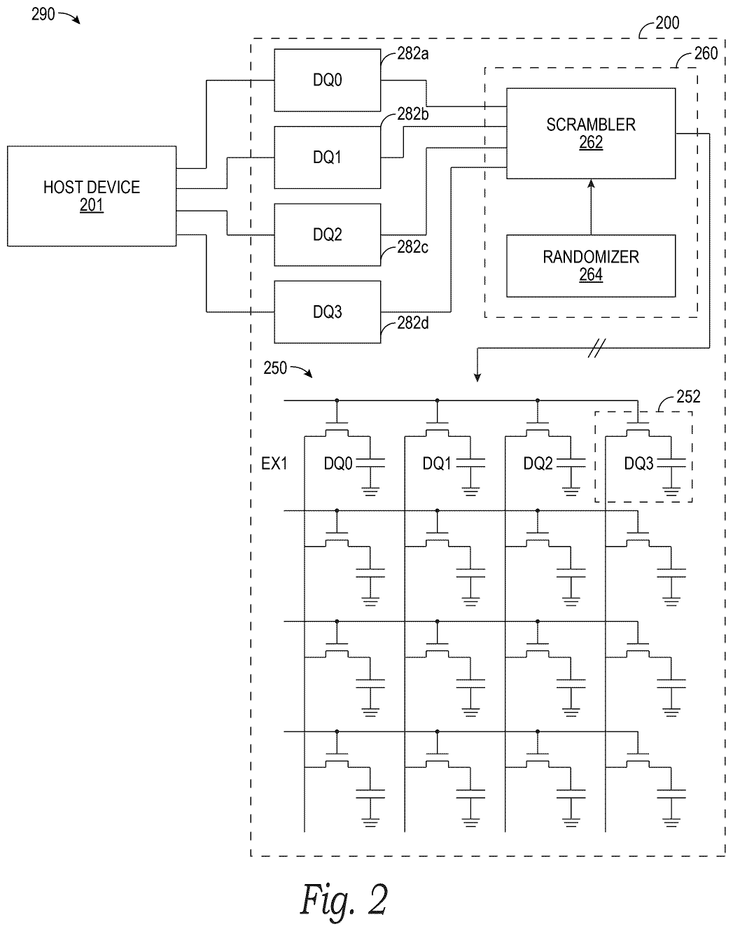

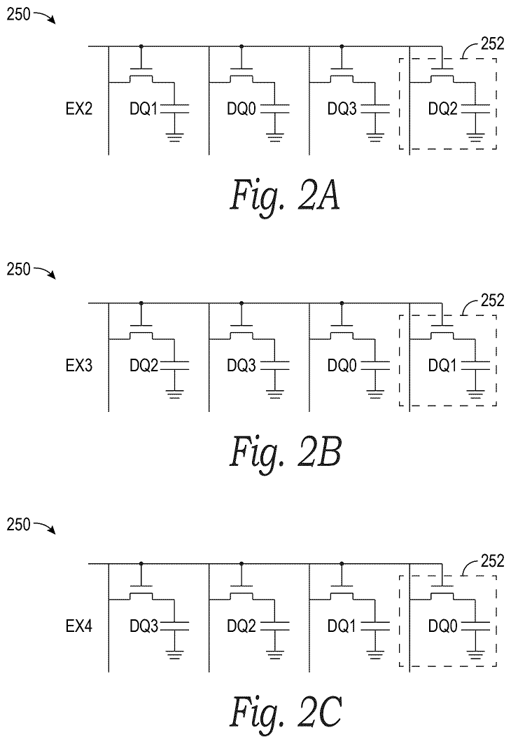

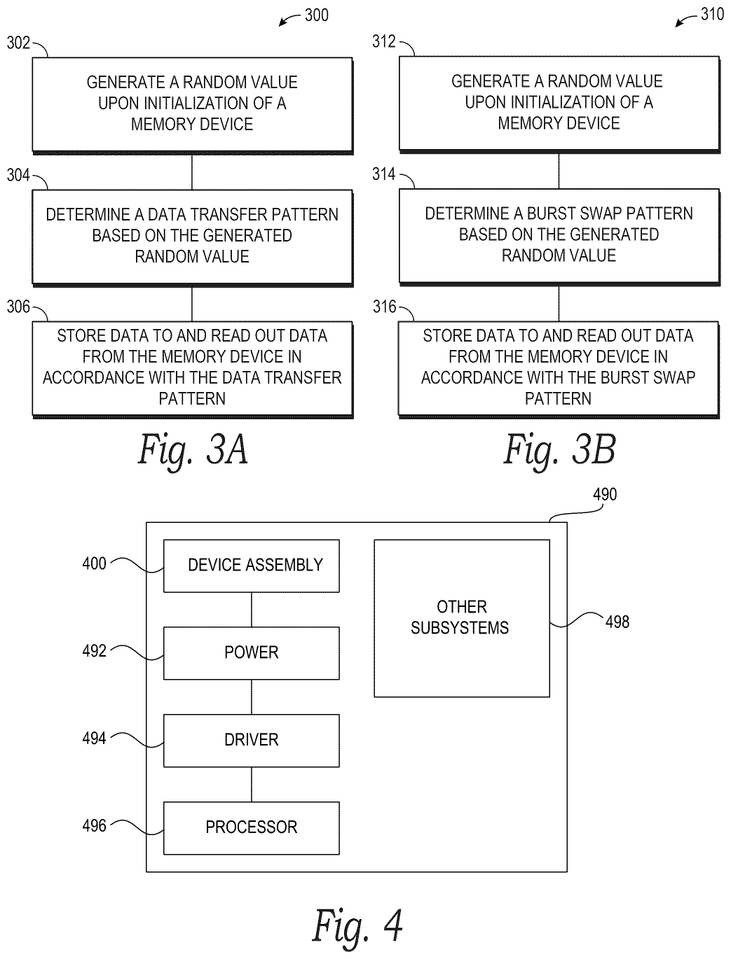

In the illustrated embodiment, the input/output circuit 160 includes a scrambler 162, a first randomizer 164, a second randomizer 166, and data burst transfer circuitry 168 (“burst circuitry 168”). As discussed in further detail below with reference to FIGS. 2 and 3A, the scrambler 162 and the first randomizer 164 can operate together to determine (e.g., set, establish, change, randomize, select, adjust, alter) pairings between the DQ terminals of the memory device 100 and memory cells of the memory array 150. Each pairing for a DQ terminal is also referred to herein as a “DQ terminal assignment” for that DQ terminal. In some embodiments, the pairings between the memory cells and the data terminals can be based at least in part on a random value that is (a) newly generated (e.g., based on a seed value) by the first randomizer 164 upon each initialization of the memory device 100 and (b) provided to the scrambler 162. Thus, for example, when power supplied to the memory device 100 is interrupted (e.g., as part of a power down event or a power loss event) and subsequently restored, the first randomizer 164 can, upon initialization of the memory device 100 after the power is restored, newly generate a random value or number that is used by the scrambler 162 to reset (e.g., determine, change, randomize, select, adjust, alter) the DQ terminal assignments. Additionally, or alternatively, the first randomizer 164 can newly generate a random value following initialization of the memory device 100 that occurs, for example, based at least in part on the memory device 100 receiving a reset signal RESET_n. Because the DQ terminal assignments are randomly reset when the memory device 100 is initialized, DQ terminal assignments used by the memory device 100 following a most recent initialization are unlikely to match the DQ terminal assignments used by the memory device 100 during a period of time between (i) an initialization immediately preceding the most recent initialization and (ii) the most recent initialization. As a result, any data that remains stored on the memory device 100 from the period of time before the most recent initialization will, if accessed following the most recent initialization, likely be read out from the memory device 100 in a scrambled and/or uninterpretable state.

The burst circuitry 168 of the memory device 100 can include parallel-to-serial conversion circuits that can convert n-bit parallel signals into serial signals, serial-to-parallel conversion circuits that can convert serial signals into n-bit parallel signals, and other circuitry that support a burst mode of the memory device 100. As discussed in further detail below with reference to FIG. 3B, the second randomizer 166 and the burst circuitry 168 can operate together to increase a number of possible ways to scramble data stored to and/or read out from the memory device 100. More specifically, the second randomizer 166 can be used to, upon each initialization of the memory device 100, newly generate (e.g., based on a seed value, such as a same seed value as used by the first randomizer 164 or a different seed value) a burst order random value. The second randomizer 166 can provide the burst order random value to the burst circuitry 168. In turn, the burst circuitry 168 can be used to set, based at least in part on the burst order random value, in which order data is (during a burst mode of the memory device 100) to be stored to memory cells of the memory array 150 and/or transferred from the memory device 100 to a connected host device (e.g., the memory controller 101, the host device 108).

Although shown as part of (and located within) the I/O circuit 160 of the memory device 100, the scrambler 162, the first randomizer 164, the second randomizer 166, and/or the burst circuitry 168 can be positioned elsewhere in the memory device 100 or external to the memory device 100 in other embodiments of the present technology. Moreover, the scrambler 162, the first randomizer 164, the second randomizer 166, and the burst circuitry 168 need not be located together or adjacent to one another. For example, all or a portion of the scrambler 162 and/or the burst circuitry 168 can be positioned at a location within or along the data path between the DQ terminals of the memory device 100 and the memory cells of the memory array 150. As specific examples, at least part of the scrambler 162 and/or at least part of the burst circuitry 168 can be positioned (a) between the DQ terminals and the I/O circuit 160, (b) between the I/O circuit 160 and the read/write amplifiers 155, (c) within the read/write amplifiers 155, (d) between the read/write amplifiers 155 and the memory array 150, and/or (e) within the memory array 150. The first randomizer 164 and/or the second randomizer 166 can be positioned at or adjacent one or more of these locations, at other locations within the memory device 100, and/or at other locations outside of the memory device 100. In some embodiments, the second randomizer 166 can be the first randomizer 164, the burst circuitry 168 can be the scrambler 162, and/or the random value used to set the DQ terminal assignments can be the same as or different from the random value used to set the burst swap order. Additionally, or alternatively, the second randomizer 166 can be different from the first randomizer, and/or the burst circuitry 168 can be different from the scrambler 162.

FIG. 2 is a partially schematic diagram of a memory system 290 configured in accordance with various embodiments of the present technology. The memory system 290 can be part of the memory system 190 of FIGS. 1A and 1B, or another memory system of the present technology. As shown, the memory system 290 includes a host device 201 communicably coupled to a plurality of DQ terminals (identified individually in FIG. 2 as DQ terminals DQ0-DQ3) of a memory device 200. The host device 201 can be a memory controller or another upstream processor (e.g., a CPU). The memory device 200 further includes (a) an input/output circuit 260 having a scrambler 262 and a randomizer 264, and (b) a memory array 250 including a plurality of memory cells 252. The scrambler 262 operably couples the DQ terminals DQ0-DQ3 to the memory cells 252 of the memory array 250, and the randomizer 264 is operably coupled to the scrambler 262.

Upon each initialization (e.g., within each new power cycle of the memory device 200, upon receiving reset signals RESET_n via the reset terminal) of the memory device 200, the randomizer 264 can (a) generate a random value (e.g., based on a seed value) and (b) transmit the generated random value to the scrambler 262. In some embodiments, the random value can be a random number. In these and other embodiments, the random value can be a random sequence, such as a random ordering of two or more numbers or values (e.g., a random ordering of four numbers or values in embodiments in which the memory device 200 includes four DQ terminals, a random ordering of eight numbers or values in embodiments in which the memory device 200 includes eight DQ terminals). In turn, the scrambler 262 can use the generated random value (also referred to herein as a “DQ random value”) received from the randomizer 264 to determine or set DQ terminal assignments or allocations (e.g., a data transfer pattern between the DQ terminals DQ0-DQ3 and the memory cells 252 of the memory array 250). The data transfer pattern can define pairings of the DQ terminals DQ0-DQ3 and the memory cells 252 of the memory array 250. For example, the data transfer pattern can define which set of memory cells 252 in the memory array 250 the memory device 200 uses to store data received from the host device 201 via a given one of the DQ terminals DQ0-DQ3. Additionally, or alternatively, the data transfer pattern can define which one of the DQ terminals DQ0-DQ3 the memory device 200 uses to read out data stored to a given set of memory cells 252 in the memory array 250.

The first row of memory cells 252 in the portion of the memory array 250 shown in FIG. 2 illustrates a first example EX1 of a data transfer pattern. FIGS. 2A-2C illustrate three other examples EX2-EX4 of data transfer patterns for this first row of memory cells 252. Each of these examples are also shown in Table 1 below:

TABLE 1

| | Column 1 | Column 2 | Column 3 | Column 4 |
|---|---|---|---|---|
| Example 1 | DQ0 | DQ1 | DQ2 | DQ3 |
| Example 2 | DQ1 | DQ0 | DQ3 | DQ2 |
| Example 3 | DQ2 | DQ3 | DQ0 | DQ1 |
| Example 4 | DQ3 | DQ2 | DQ1 | DQ0 |

As illustrated by examples EX1-EX4, the four memory cells 252 in the first row of the illustrated portion of the memory array 250 can be randomly assigned to any one of the DQ terminals DQ0-DQ3 based on the random value generated by the randomizer 264. More specifically, referring to the first example EX1 illustrated in FIG. 2, the scrambler 262 can (based on a first random value received from the randomizer 264 for a first initialization/power cycle of the memory device 200) assign the first memory cell 252 of the first row to DQ terminal DQ0, the second memory cell 252 of the first row to DQ terminal DQ1, the third memory cell 252 of the first row to DQ terminal DQ2, and the fourth memory cell 252 of the first row to DQ terminal DQ3. Therefore, in this first example EX1, when data is received from the host device 201 at DQ terminal DQ1, the scrambler 262 can cause the memory device 200 to use the second memory cell 252 (and/or one or more other memory cells 252 of the memory array 250 that have been assigned to the DQ terminal DQ1) to store the data. Additionally, or alternatively, in this first example EX1, when data is read out of the second memory cell 252, the scrambler 262 can cause the memory device 200 to transmit the data to the host device 201 via the DQ terminal DQ1. Similarly, in the first example EX1, when data is received from the host device 201 at DQ terminal DQ3, the scrambler 262 can cause the memory device 200 to use the fourth memory cell 252 (and/or one or more other memory cells 252 of the memory array 250 that have been assigned to the DQ terminal DQ3) to store the data. Additionally, or alternatively, in this first example EX1, when data is read out from the fourth memory cell 252, the scrambler 262 can cause the memory device 200 to transmit the data to the host device 201 via the DQ terminal DQ3.

In other words, at least until the memory device 200 next executes an initialization routine, when data is received from a connected host device (e.g., the host device 201) at the DQ terminals DQ0-DQ3 of the memory device 200, the memory device 200 (a) can scramble the data using the scrambler 262 by routing data bits received at each one of the DQ terminals DQ0-DQ3 to memory cells 252 of the memory array 250 that have been paired with that one of the DQ terminals DQ0-DQ3 as defined by the data transfer pattern (example EX1), and (b) can store the data bits in all or a subset of those memory cells 252. Thereafter, prior to the next initialization, as the data is read out from the memory array 250, the memory device 200 (a) can unscramble the data using the scrambler 262 and in accordance with the data transfer pattern (example EX1) and (b) can transmit the data to the host device 201 via the DQ terminals DQ0-DQ3. Because the same data transfer pattern (example EX1) is used by the scrambler 262 to both scramble and unscramble the data, a connected host device (e.g., the host device 201) can store the data to and retrieve the data from the memory device 200 without issue. In addition, in the illustrated embodiment, the memory device 200 internally handles the scrambling and unscrambling of the data while the connected host device 201 remains unaware of the current data transfer pattern (example EX1) implemented within the memory device 200.

Referring now to the second example EX2 illustrated in FIG. 2A, the scrambler 262 can (based on a second random value received from the randomizer 264 upon a next initialization of the memory device 200) assign the first memory cell 252 of the first row to DQ terminal DQ1, the second memory cell 252 of the first row to DQ terminal DQ0, the third memory cell 252 of the first row to DQ terminal DQ3, and the fourth memory cell 252 of the first row to DQ terminal DQ2. Therefore, in this second example EX2, when data is received from the host device 201 at DQ terminal DQ1, the scrambler 262 can cause the memory device 200 to use the first memory cell 252 (or another memory cell 252 of the memory array 250 that has been assigned to the DQ terminal DQ1) to store the data. Additionally, or alternatively, in the second example EX2, when data is read out of the second memory cell 252, the scrambler 262 can cause the memory device 200 to transmit the data to the host device 201 via the DQ terminal DQ0. Similarly, in the second example EX2, when data is received from the host device 201 at DQ terminal DQ3, the scrambler 262 can cause the memory device 200 to use the third memory cell 252 (or another memory cell 252 of the memory array 250 that has been assigned to the DQ terminal DQ3) to store the data. Additionally, or alternatively, in the second example EX2, when data is read out from the fourth memory cell 252, the scrambler 262 can cause the memory device 200 to transmit the data to the host device 201 via the DQ terminal DQ2.

In other words, similar to the first example EX1 discussed above, the memory device 200 internally handles the scrambling and unscrambling of the data while the connected host device remains unaware of the current data transfer pattern (example EX2) implemented within the memory device 200. In addition, when the same data transfer pattern (example EX2) is used by the scrambler 262 to both scramble and unscramble the data, a connected host device (e.g., the host device 201) can store the data to and retrieve the data from the memory device 200 without issue.

When, however, a different data transfer pattern is used to attempt to unscramble data read from the memory array 250 than the data transfer pattern used to scramble the data when it was being stored to the memory array 250, the data can remain scrambled as it is read out of the memory device 200 to a connected host device (e.g., the host device 201) via the DQ terminals DQ0-DQ3. For example, consider a comparison between the data transfer pattern of the first example EX1 (FIG. 2) and the data transfer pattern of the second example EX2 (FIG. 2A). Following a first initialization of the memory device 200, the memory device 200 can (a) use the scrambler 262 to, in accordance with the first data transfer pattern (example EX1), scramble data received from a connected host device at the DQ terminals DQ0-DQ3 and (b) store the scrambled data in memory cells 252 of the memory array 250. As a specific example, assume four bits (0110) are received at the DQ terminals DQ0-DQ3, respectively, from a connected host device. These four bits (0110) can be scrambled by the scrambler 262 and stored to the first row of memory cells 252 of the memory array 250 in accordance with the data transfer pattern (example EX1) such that the memory cells 252 of the first row of the memory array 250 store the four bits as 0110 across the first row (reading the memory cells 252 in order from left to right). As long as the memory device 200 does not execute an initialization routine, remains in the same power cycle, and/or continues to use the first data transfer pattern (example EX1), when the four data bits (0110) are read out of the first row of the memory array 250, the scrambler 262 can unscramble the four data bits (0110) and route them to the DQ terminals DQ0-DQ3 such that they are output as 0110 from the memory device 200 to the connected host device (e.g., the host device 201) via the DQ terminals DQ0-DQ3, respectively. Therefore, the connected host device can receive the four data bits (0110) in a same, unscrambled state as the data bits (0110) were initially transmitted from the connected host device to the memory device 200.

Assume now that, after storing the four bits (0110) to the first row of the memory array 250 in accordance with the first data transfer pattern (example EX1), the memory device 200 undergoes a second initialization (e.g., following a power down event or a power loss event that causes the memory device 200 to execute the initialization routine when power is restored, such as in the next power cycle of the memory device 200). Upon the second initialization, the randomizer 264 newly generates a random value that is used by the scrambler 262 to change the implemented data transfer pattern to the second data transfer pattern (example EX2) shown in FIG. 2A. Thereafter, when a connected host device (e.g., the host device 201 or another host device) attempts to access (e.g., read) the four data bits (0110) stored to the memory cells 252 of the first row of the memory array 250, the scrambler 262 attempts to unscramble the four data bits (0110) in accordance with the second data transfer pattern (example EX2) as opposed to in accordance with the first data transfer pattern (example EX1). As a result, the four data bits (0110) are output from the memory device 200 to the connected host device via the DQ terminals DQ0-DQ3 as 1001, respectively. In other words, the four data bits (0110) are output from the memory device 200 in a scrambled state. And because the connected host device is not aware of (i) the first data transfer pattern (example EX1) that was used to initially scramble the four data bits (0110) at the time the four data bits (0110) were stored to the memory array 250 or (ii) the second data transfer pattern (example EX2) that was used to attempt to unscramble the four data bits (0110) as they were read out of the memory device 200, the connected host device in unlikely to be able to unscramble the four data bits (0110) into the proper order. Stated another way, the present technology is expected to maintain security of the data across execution of an initialization routine and/or across different power cycles of a memory device.

FIGS. 2B and 2C illustrate a third example EX3 and a fourth example EX4 of two other possible data transfer patterns that can be utilized within the memory device 200. Indeed, given that the memory device 200 illustrated in FIG. 2 includes four DQ terminals DQ0-DQ3, FIGS. 2 and 2A-2C illustrate four of 24 possible different data transfer patterns (calculated as

$$\frac{n !}{( n - r ) !}$$

Or as n! when n=r, where n is the number of DQ terminals and r is the number of DQ terminals utilized in each data transfer pattern) that can be utilized within the memory device 200. As such, the probability that the randomizer 264 newly generates a random value corresponding to a specific one of the 24 data transfer patterns during an initialization of the memory device 200 can be calculated as

$$\frac{1}{n !} ,$$

where n represents the number of DQ terminals. Thus, in the example illustrated in FIG. 2, because the memory device 200 includes four DQ terminals (DQ terminals DQ0-DQ3), the probability of the memory device 200 utilizing the same data transfer pattern immediately before and immediately after a given initialization of the memory device 200 is

$$\frac{1}{4 !} ,$$

which is equivalent to 1/24 or approximately 4.167%. Stated another way, there is approximately a 4.167% chance that the memory device 200 utilizes the same data transfer pattern for (a) a first period of time extending between a first initialization of the memory device 200 and a second, consecutive initialization of the memory device 200 and (b) a second period of time extending between the second initialization of the memory device 200 and a third, consecutive initialization of the memory device 200. Were this to occur, data stored to the memory device 200 during the first period of time could be read out of the memory device 200 in an unscrambled state during the second period of time.

But this is merely the probability of the memory device 200 illustrated in FIG. 2 utilizing the same data transfer pattern immediately before a given initialization and immediately after the given initialization. As is shown in the embodiment illustrated in FIG. 1A, a connected host device (e.g., the host device 201 of FIG. 2) may often be coupled to a plurality of memory devices 200 that are used by the connected host device to store data. In these embodiments, the randomizer 264 of each of the memory devices 200 can, independently of one another, newly generate a random value upon each initialization of the corresponding memory device 200. Therefore, assuming that each of the memory devices 200 includes four DQ terminals, the probability of multiple ones of the memory devices 200 each utilizing a same data transfer pattern across a given initialization is

$${( \frac{1}{24} )}^{x} ,$$

where x is the number of memory devices 200 included in the multiple one of the memory devices 200. Thus, the probability for just two memory devices 200 each utilizing a same data transfer pattern across a given initialization is approximately 0.174%.

The probabilities highlighted in the above examples decrease even further for memory devices that utilize a greater number of DQ terminals. For example, memory devices configured in accordance with other embodiments of the present technology can include another number of DQ terminals, such as eight or sixteen DQ terminals, in which (a) the probability that a memory device utilizes a same data transfer pattern across a given initialization is significantly less than 4.167% and (b) the probability that two or more memory devices each utilize a same data transfer pattern across a given initialization is significantly less than 0.174%.

In some embodiments, one of the possible data transfer patterns for a memory device can correspond to no scrambling of DQ terminal assignments. For example, the data transfer pattern of the first example EX1 illustrated in FIG. 2 can correspond to no scrambling of DQ terminal assignments such that, for example, data bits received at DQ terminal DQ0 of the memory device 200 are stored to the same set of memory cells 252 of the memory array 250 as they would be if the scrambler 262 and the randomizer 264 were disabled. Therefore, in some embodiments of the present technology, the data transfer pattern that corresponds to no scrambling of DQ terminal assignments can be removed or omitted as one of the potential options for data transfer patterns that can be implemented in a memory device of the present technology (e.g., when the scrambler 262 and/or the randomizer 264 are enabled). As a result, a memory device in such embodiments is guaranteed to scramble data received at DQ terminals of the memory device, with a slight increase in the probability that the memory device uses a same data transfer pattern across a given initialization of the memory device.

Referring back to FIG. 1B, in some embodiments, the second randomizer 166 can be a burst order randomizer that is usable to provide additional scrambling of data. The second randomizer 166 can be operably coupled to the scrambler 162 and/or to the burst circuitry 168 of the memory device 100, and can be configured to generate a random value (e.g., based on a seed value) upon initialization of the memory system 190 or the memory device 100. In some embodiments, the random value can be a random number. In these and other embodiments, the random value can be a random sequence, such as a random ordering or two or more numbers or values (e.g., eight numbers or values in embodiments in which a burst length is eight). The scrambler 162 and/or the burst circuitry 168 can use the random value (also referred to herein as a burst order random value) to set a burst swap pattern. The burst swap pattern can define an order in which, during a burst mode of the memory device 100, data is stored to the memory cells of the memory array 150 and/or is read out of the memory device 100 (e.g., and transferred to a connected host device, such as the host device 108 and/or the memory controller 101). Analogous to the randomization of the DQ terminal pairings described herein, the memory device 100 is configured to use a burst swap pattern until the memory device 100 next executes an initialization routine. Thus, for a first period of time extending between a first initialization and a second, consecutive initialization, a first burst swap pattern can be used (a) to input data into and/or store data in the memory device 100 and (b) to read out data stored to the memory device 100. Thereafter, the second randomizer 166 can newly generate a burst order random value upon the second initialization of the memory device 100, and the burst order random value can be used to set a second burst swap pattern for a second period of time extending between the second initialization and a third, consecutive initialization. The probability that the newly generated burst order random value for the second period of time matches the burst order random value for the first period of time can be calculated as 2^{-m}, where m represents the burst length. For example, in an example in which the burst length is eight (8), the probability of a newly generated burst order random value matching an immediately preceding burst order random value used by the memory device 100 can be calculated as 2⁻⁸, or approximately 0.39%.

In some embodiments, one of the possible burst swap patterns for a memory device can correspond to no burst order swapping. For example, a burst swap pattern of a memory device can correspond to no burst order swapping such that, when the memory device operates in a burst mode, data bits are serialized and/or parallelized in the same order that they would be if the scrambler 162 and/or the second randomizer 166 were disabled. Therefore, in some embodiments of the present technology, the burst swap pattern that corresponds to no burst order swapping can be removed or omitted as one of the potential options for burst swap patterns that can be implemented in a memory device of the present technology (e.g., when the scrambler 162 and/or the second randomizer 166 are enabled). As a result, a memory device in such embodiments is guaranteed to swap the order in which data bits are serialized and/or parallelized, with a slight increase in the probability that the memory device uses a same burst swap pattern across a given initialization of the memory device.

In some embodiments of the present technology, the memory device 100 can combine use of the first randomizer 164 (e.g., to set a data transfer pattern) and the second randomizer 166 (e.g., to set a burst swap pattern). For example, assuming that the memory device 100 includes eight (8) DQ terminals and uses a burst length of eight (8) when operating in burst mode, the probability that a same data transfer pattern and a same burst swap pattern will be used across a given initialization of the memory device 100 is

$$\frac{1}{8 !} \times {2}^{- 8} ,$$

or approximately 0.00000969%. Stated another way, for data stored to the memory device 100 prior to a given initialization of the memory device 100, there is approximately a 0.00000969% chance of correctly reading out the data from the memory device 100 following the given initialization of the memory device 100. This chance is even further reduced in embodiments in which a connected host device uses several memory devices 100 to store data (as is shown in FIG. 1A) and that each scramble and unscramble data independently of one another. Thus, compounding the two different randomization methods disclosed herein can further reduce the probability of successful, unauthorized access of data across an initialization of the memory device 100.

FIG. 3A is a flowchart illustrating a method 300 for scrambling data in accordance with various embodiments of the present technology. The method 300 can be used to scramble and/or unscramble data as the data is stored to and/or read from a memory device, such as the memory device 100 of FIGS. 1A and 1B and/or the memory device 200 of FIG. 2. The method 300 is illustrated as a set of steps or blocks 302, 304, and 306. All or a portion of one or more of the blocks 302, 304, and 306 can be performed or executed by one or more components of a memory system, such as one or more components of a memory device, a memory controller, and/or an upstream host device or CPU. All or a subset of one or more of the blocks 302, 304, and/or 306 can be executed in accordance with the discussion above and/or with the discussion of FIGS. 3B and 4 below.

The method 300 begins at block 302 by generating a random value upon initialization of a memory device (e.g., upon entering a new power cycle, after receiving a reset signal RESET_n). The memory device can include a plurality of DQ terminals (e.g., the DQ terminals DQ0-DQ3 of FIG. 2) and a memory array (e.g., the memory array 150 of FIG. 1B, the memory array 250 of FIGS. 2 and 2A-2C) including a plurality of memory cells (e.g., the memory cells 252 of FIGS. 2 and 2A-2C). At block 304, the method 300 continues by determining a data transfer pattern based on the generated random value. As discussed above, the data transfer pattern can define which set of memory cells in the memory array the memory device uses to store data received at a given one of the DQ terminals. Additionally, or alternatively, the data transfer pattern can define which one of the DQ terminals the memory device uses to read out data stored to a given set of memory cells in the memory array. At block 306, the method 300 continues by storing data to and/or reading data from the memory device in accordance with the determined data transfer pattern.

In some embodiments, the method 300 can further include (1) generating, upon a next (e.g., a consecutive, successive, subsequent, immediately subsequent) initialization of the memory device (e.g., following a power down event or a power loss event, during power up of the memory device, in response to receiving a reset command RESET_n), a second random value, (2) determining a second data transfer pattern based on the generated second random value, and (3) storing data to and/or reading data from the memory device in accordance with the determined second data transfer pattern. In some embodiments, the second data transfer pattern is different from the data transfer pattern described above with reference to blocks 302, 304, and 306 such that storing data to and/or reading data from the memory device in accordance with the determined second data transfer pattern utilizes different DQ terminal pairings than are utilized to store data to and/or read data from the memory device in accordance with the data transfer pattern described above with reference to blocks 302, 304, and 306.

In some embodiments, all or a portion of one or more of the steps or blocks 302, 304, and/or 306 of the method 300 can be performed by one or more components of the memory device. For example, the memory device can include a scrambler operably coupled to the data terminals and the memory cells, and configured to set the data transfer pattern based at least in part on a random value generated by and/or received from a randomizer of the memory device.

Although the blocks 302, 304, and 306 of the method 300 are discussed and illustrated in a particular order, the method 300 illustrated in FIG. 3A is not so limited. In other embodiments, the method 300 can be performed in a different order. In these and other embodiments, any of the blocks 302, 304, and 306 of the method 300 can be performed before, during, and/or after any of the other blocks 302, 304, and 306 of the method 300. Moreover, a person of ordinary skill in the relevant art will recognize that the illustrated method 300 can be altered and still remain within these and other embodiments of the present technology. For example, one or more of the blocks 302, 304, and 306 of the method 300 illustrated in FIG. 3A can be omitted and/or repeated in some embodiments. As a specific example, the method 300 can include generating two or more random values upon initialization of a power cycle of a memory device. As another specific example, storing data to and/or reading data from the memory device can be performed without first determining a data transfer pattern, such as by disabling the scrambler and/or the randomizer(s) of the memory device. Thus, in these embodiments, all or a portion of blocks 302, 304, and/or 306 can be omitted.

FIG. 3B is a flowchart illustrating another method 310 for scrambling data in accordance with various embodiments of the present technology. The method 310 can be used to scramble and/or unscramble data as the data is stored to and/or read from a memory device, such as the memory device 100 of FIGS. 1A and 1B and/or the memory device 200 of FIG. 2. The method 310 is illustrated as a set of steps or blocks 312, 314, and 316. All or a portion of one or more of the blocks 312, 314, and 316 can be performed or executed by one or more components of a memory system, such as one or more components of a memory device and/or a memory controller. All or a subset of one or more of the blocks 312, 314, and/or 316 can be executed in accordance with the discussion above and/or with the discussion of FIG. 4 below.

The method 310 begins at block 312 by generating a random value upon initialization of a memory device (e.g., upon entering a new power cycle, after receiving a reset signal RESET_n). At block 314, the method 310 continues by determining a burst swap pattern based on the generated random value. As discussed above, the burst swap pattern can define an order in which, during a burst mode of the memory device, data is serialized and stored to the memory cells of the memory array 150 and/or is parallelized and read out of the memory device 100 (e.g., to a connected host device). At block 316, the method 310 continues by storing data to and/or reading data from the memory device in accordance with the determined burst swap pattern. In some embodiments, storing data to the memory device in accordance with the burst swap pattern can include serializing, for storage in the memory array of the memory device, data (received at the DQ terminals of the memory device) in an order defined by the burst swap pattern. In these and other embodiments, reading data from the memory device in accordance with the determined burst swap pattern can include parallelizing, for transfer to a connected host device via the DQ terminals, data (read from the memory array) in an order defined by the burst swap pattern.

In some embodiments, the method 310 can further include (1) generating, upon a next (e.g., a consecutive, successive, subsequent, immediately subsequent) initialization of the memory device (e.g., following a power down event a power loss event, during power up of the memory device, in response to receiving a reset command RESET_n), a second random value, (2) determining a second burst swap pattern based on the generated second random value, and (2) storing data to and/or reading data from on the memory device in accordance with the determined second burst swap pattern. In some embodiments, the second burst swap pattern is different from the burst swap pattern described above with reference to blocks 312, 314, and 316 such that storing data to and/or reading data from the memory device in accordance with the determined second burst swap pattern serializes and/or parallelizes data in a different order than the order in which data is serialized and/or parallelized when stored to and/or read from the memory device in accordance with the burst swap pattern described above with reference to blocks 312, 314, and 316.

Although the blocks 312, 314, and 316 of the method 310 are discussed and illustrated in a particular order, the method 310 illustrated in FIG. 3B is not so limited. In other embodiments, the method 310 can be performed in a different order. In these and other embodiments, any of the blocks 312, 314, and 316 of the method 310 can be performed before, during, and/or after any of the other blocks 312, 314, and 316 of the method 310. Moreover, a person of ordinary skill in the relevant art will recognize that the illustrated method 310 can be altered and still remain within these and other embodiments of the present technology. For example, one or more of the blocks 312, 314, and 316 of the method 310 illustrated in FIG. 3B can be omitted and/or repeated in some embodiments.

In some embodiments, the method 300 and the method 310 (or portions thereof) can be combined. For example, a combined method can include, upon each initialization of a memory device, generating a first random value for determining a data transfer pattern and a second random value for determining a burst swap pattern, determining the data transfer pattern and the burst swap pattern based on the first and second random values, respectively, and storing data to and/or reading data from the memory device in accordance with the determined data transfer pattern and the determined burst swap pattern. As discussed above, compounding the two randomization techniques can significantly increase the probability that security of data stored to the memory device is maintained across an initialization of the memory device and/or across multiple power cycles of the memory device.

FIG. 4 is a schematic view showing a system 400 comprising a semiconductor device assembly 402 that can include memory devices configured in accordance with an embodiment of the present technology. Semiconductor device assemblies including the memory devices described above with reference to FIGS. 1A-3B can be incorporated into any of a myriad of larger and/or more complex systems, such as the system 400 illustrated. The system 400 can include the semiconductor device assembly 402 (or a discrete semiconductor device), a power source 404, a driver 406, a processor 408, and/or other subsystems or components 410. The semiconductor device assembly 402 can include memory devices with features generally similar to those of the memory devices described above with reference to FIGS. 1A-3B, such as the scrambler 162, the first randomizer 164 (e.g., the data terminal randomizer), and/or the second randomizer 166 (e.g., the burst order randomizer). The resulting system 400 can perform any of a wide variety of functions, such as memory storage, data processing, and/or other suitable functions. Accordingly, representative systems 400 can include, without limitation, hand-held devices (e.g., mobile phones, tablets, digital readers, and digital audio players), computers, vehicles, appliances, and other products. Components of the system 400 may be housed in a single unit or distributed over multiple, interconnected units (e.g., through a communications network). The components of the system 400 can also include remote devices and any of a wide variety of computer readable media. As discussed herein, the semiconductor device assemblies with memory devices configured in accordance with embodiments of the present technology are expected to better protect stored data across initializations of the memory devices and/or across power cycles of the memory devices.

### Conclusion

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. An apparatus, comprising:
a memory array including a plurality of memory cells;
a plurality of data (DQ) terminals operably coupled to the memory array; and
circuitry configured to, upon each initialization of the apparatus—
set a data transfer pattern for the apparatus to a random one of a plurality of data transfer patterns for the apparatus, wherein each data transfer pattern of the plurality of data transfer patterns defines a different allocation of memory cells of the plurality of memory cells to DQ terminals of the plurality of DQ terminals; or
set a burst swap order for the apparatus to a random one of a plurality of burst swap orders for the apparatus, wherein each burst swap order of the plurality of burst swap orders defines a different order in which the apparatus is configured to parallelize or serialize data received or output, respectively, via the plurality of DQ terminals.

2. The apparatus of claim 1, wherein the circuitry includes:
a randomizer configured to newly generate a random value upon each initialization of the apparatus; and
a scrambler configured to, upon each initialization of the apparatus, newly set the data transfer pattern for the apparatus based at least in part on the newly generated random value.

3. The apparatus of claim 1, wherein the circuitry includes:
a randomizer configured to newly generate a random value upon each initialization of the apparatus; and
burst swap circuitry configured to, upon each initialization of the apparatus, newly set the burst swap order for the apparatus based at least in part on the newly generated random value.

4. The apparatus of claim 1, wherein the circuitry is configured to, upon each initialization of the apparatus, both—
set the data transfer pattern for the apparatus to the random one of the plurality of data transfer patterns; and
set the burst swap order for the apparatus to the random one of the plurality of burst swap orders.

5. The apparatus of claim 4, wherein the circuitry is configured to:
set the data transfer pattern based on a first random value that is newly generated upon each initialization of the apparatus; and
set the data transfer pattern based on a second random value that is newly generated upon each initialization of the apparatus.

6. The apparatus of claim 5, wherein the first random value and the second random value are independently generated from one another upon each initialization of the apparatus.

7. The apparatus of claim 1, wherein upon a first initialization of the apparatus, the circuitry is configured to—
set the data transfer pattern for the apparatus to a first random one of the plurality of data transfer patterns such that, during a first period of time following the first initialization and before a second initialization of the apparatus, the apparatus is configured to output, via a first DQ terminal of the plurality of DQ terminals, first data received via the first DQ terminal during the first period of time, or
set the burst swap order for the apparatus to a first random one of the plurality of burst swap orders such that, during the first period of time, the apparatus is configured to parallelize or serialize, in accordance with a first order, second data received or output, respectively, via the plurality of DQ terminals.

8. The apparatus of claim 7, wherein upon a second initialization of the apparatus, the circuitry is configured to—
set the data transfer pattern for the apparatus to a second random one of the plurality of data transfer patterns such that, during a second period of time following the second initialization, the apparatus is configured to output the first data via a second DQ terminal of the plurality of DQ terminals that is different from the first DQ terminal, or
set the burst swap order for the apparatus to a second random one of the plurality of burst swap orders such that, during the second period of time, the apparatus is configured to serialize, in accordance with a second order different from the first order, the second data when the second data is output from the plurality of DQ terminals.

9. The apparatus of claim 8, wherein the first initialization and the second initialization are consecutive initializations of the apparatus.

10. The apparatus of claim 8, wherein:
the second period of time extends between the second initialization and a third initialization of the apparatus; and
upon the second initialization of the apparatus, the circuitry is configured to—
set the data transfer pattern for the apparatus to the second random one of the plurality of data transfer patterns such that, during the second period of time, the apparatus is configured to output, via the first DQ terminal, third data received via the first DQ terminal during the second period of time, or
set the burst swap order for the apparatus to the second random one of the plurality of burst swap orders such that, during the second period of time, the apparatus is configured to parallelize or serialize, in accordance with the second order, fourth data received via the plurality of DQ terminals during the second period of time.

11. A method, comprising:
upon an initialization of a memory device—
setting a data transfer pattern for the memory device to a random one of a plurality of data transfer patterns for the memory device, wherein each data transfer pattern of the plurality of data transfer patterns defines a different allocation of (a) memory cells in a memory array of the memory device to (b) a plurality of data (DQ) terminals of the memory device; or
setting a burst swap order for the memory device to a random one of a plurality of burst swap orders for the memory device, wherein each burst swap order of the plurality of burst swap orders defines a different order in which the memory device is configured to parallelize or serialize data received or output, respectively, via the plurality of DQ terminals.

12. The method of claim 11, wherein:
the initialization is first initialization, the random one of the plurality of data transfer patterns is a first random one of the plurality of data transfer patterns, and the random one of the plurality of burst swap orders is a first random one of the plurality of burst swap orders; and
the method further comprises, upon a second initialization of the memory device—
setting the data transfer pattern for the memory device to a second random one of the plurality of data transfer patterns for the memory device; or
setting the burst swap order for the memory device to a second random one of the plurality of burst swap orders for the memory device.

13. The method of claim 12, wherein:
the first initialization and the second initialization are consecutive initializations of the memory device; and
the method further comprises, after the first initialization of the memory device and before the second initialization of the memory device—
receiving, at the memory device, first data via the plurality of DQ terminals,
storing the first data to the memory array in accordance with the first random one of the plurality of data transfer patterns or parallelizing the first data in accordance with the first random one of the plurality of burst swap orders, and
outputting the first data via the plurality of DQ terminals, wherein outputting the first data includes:
outputting the first data via the plurality of DQ terminals in accordance with first random one of the plurality of data transfer patterns such that each data bit of the first data is output from the memory device via a same DQ terminal of the plurality of DQ terminals through which the data bit was received at the memory device; or
serializing the first data in accordance with the first random one of the plurality of burst swap orders such that the first data is output from the plurality of DQ terminals in a same order as the first data was received at the memory device.

14. The method of claim 12, wherein:
the first initialization and the second initialization are consecutive initializations of the memory device;
the method further comprises, after the first initialization of the memory device and before the second initialization of the memory device—
receiving, at the memory device, first data via the plurality of DQ terminals, and
storing the first data to the memory array in accordance with the first random one of the plurality of data transfer patterns or parallelizing the first data in accordance with the first random one of the plurality of burst swap orders; and
the method further comprises, after the second initialization of the memory device, outputting the first data via the plurality of DQ terminals, wherein outputting the first data includes:
outputting the first data via the plurality of DQ terminals in accordance with the second random one of the plurality of data transfer patterns such that at least one data bit of the first data is output from the memory device via a different DQ terminal of the plurality of DQ terminals than a DQ terminal of the plurality of DQ terminals through which the data bit was received at the memory device, or
serializing the first data in accordance with the second random one of the plurality of burst swap orders such that the first data is output from the plurality of DQ terminals in a different order from an order in which the first data was received at the memory device.

15. The method of claim 11, wherein:
setting the data transfer pattern includes setting the data transfer pattern based at least in part on a first random value generated upon the initialization of the memory device; or
setting the burst swap order includes setting the burst swap order based at least in part on a second random value generated upon the initialization of the memory device.

16. The method of claim 15, wherein:
the method further comprises, upon the initialization of the memory device, generating the first random value or the second random value;
generating the first random value or the second random value includes generating the first random value or the second random value, respectively, internally within the memory device; and
setting the data transfer pattern or setting the burst swap order includes setting the data transfer pattern or setting the burst swap order, respectively, internally within the memory device.

17. A memory system, comprising:
a host device; and
a plurality of memory devices operably coupled to the host device, each memory device of the plurality of memory devices including:
a memory array comprising a plurality of memory cells;
a plurality of data (DQ) terminals operably coupled to the memory array; and
circuitry configured to, upon each initialization of the memory device—
set a data transfer pattern for the memory device to a random data transfer pattern of a plurality of data transfer patterns for the memory device, wherein each data transfer pattern of the plurality of data transfer patterns defines a different allocation of memory cells of the plurality of memory cells to DQ terminals of the plurality of DQ terminals; or
set a burst swap order for the memory device to a random burst swap order of a plurality of burst swap orders for the memory device, wherein each burst swap order of the plurality of burst swap orders defines a different order in which the memory device is configured to parallelize or serialize data received or output, respectively, via the plurality of DQ terminals.

18. The memory system of claim 17, wherein the circuitry of each memory device is further configured to, upon each initialization of the memory device—
generate a random value; and
set the data transfer pattern for the memory device to the random data transfer pattern based at least in part on the random value.

19. The memory system of claim 17, wherein the circuitry of each memory device is further configured to, upon each initialization of the memory device—
generate a random value; and
set the burst swap order for the memory device to the random burst swap order based at least in part on the random value.

20. The memory system of claim 17, wherein the circuitry of each memory device is configured to, upon each initialization of the memory device, both—
set the data transfer pattern for the memory device to the random data transfer pattern; and
set the burst swap order for the memory device to the random burst swap order.
